(19) United States
(12) Patent Application Publication
(10) Pub. No.: US 2026/0082981 A1
(43) Pub. Date: Mar. 19, 2026

(54) CHIP PACKAGING STRUCTURE AND PREPARATION METHOD

(71) Applicant: SJ Semiconductor(Jiangyin) Corporation, Jiangyin (CN)

(72) Inventors: Yenheng CHEN, Jiangyin (CN); Chengchung LIN, Jiangyin (CN); Jin YANG, Jiangyin (CN)

(73) Assignee: SJ Semiconductor(Jiangyin) Corporation, Jiangyin, JS (CN)

(21) Appl. No.: 19/108,745

(22) PCT Filed: Jun. 8, 2023
(86) PCT No.: PCT/CN2023/099209

§ 371 Date: Mar. 5, 2025

(30) Foreign Application Priority Data
Sep. 7, 2022 (CN) 202211086731.3

(51) Int. Cl. H01L 23/31; H01L 21/48; H01L 21/56; H01L 23/367; H01L 23/538; H01L 25/03

(52) U.S. Cl. CPC H10W 74/117; H10W 70/093; H10W 70/095; H10W 70/611; H10W 74/016; H10W 90/00; H10W 90/401; H10W 40/226; H10W 40/228

(57) ABSTRACT

The chip package structure and a method are disclosed, comprising: a substrate, a first rewiring layer, a first chip, a dummy wafer, a laminate layer, a second rewiring layer, a second chip, a metal connection through-hole, and a heat dissipation element. By introducing a dummy wafer with a lower thermal expansion coefficient on both sides of the first chip, the mismatch of the thermal expansion coefficient of the encapsulation structure can be reduced, and the warping generated by the chip during the encapsulation process can be reduced. By forming a metal connecting post between the first chip and the second chip, a heat dissipation passage is established to further reduce the encapsulation thermal resistance and thus improve the heat dissipation efficiency of the chip, so as to form a chip encapsulation structure with a better heat dissipation performance by combining heat dissipation elements.

### TECHNICAL FIELD

The present invention relates to the field of semiconductor packaging technology, and in particular relates to a chip packaging structure and a preparation method.

### BACKGROUND

With the increasing functionality, performance, and integration of integrated circuits (IC), as well as the emergence of new types of ICs, packaging technology has been playing an increasingly important role in IC products and accounts for an increasing proportion of the value of the entire electronic system. Currently, advanced packaging methods include: wafer-level chip scale packaging, fan-out wafer-level packaging, flip chip, stacked packaging, and so on. Wafer-level chip packaging is a new type of chip packaging technology with great application prospects, it is different from the traditional chip packaging process where the chip is first cut and then packaged and tested, but instead the process does package and tests on the whole wafer followed by cutting wafer into bare chips, this process not only saves cost of packaging and testing, but also significantly reduces the size of the finished chip after encapsulation.

In the fan-out wafer-level chip packaging process, no further thinning is performed for large-size thick silicon chips, the thinning process can cause a sharp increase in chip warpage due to mismatch of thermal expansion coefficients among the silicon chips, the redistribution layers, and the carriers. At the same time, due to the increasing power from packaging process, multiple-chip packages in the same package structure are more likely to form a heat source, which puts forward higher requirements for the heat dissipation of the package structure.

Therefore, it is necessary to provide a chip package structure and a preparation method to solve the above problems.

### SUMMARY

The present invention is to provide a chip packaging structure and a preparation method for solving the problems of a sharp increase in chip warpage and a low heat dissipation efficiency of chips in the packaging structure during the packaging process in the existing techniques.

The present invention provides a method of preparing a chip encapsulation structure, comprising the following steps:
providing a temporary substrate, forming a separation layer on the temporary substrate;
forming a first rewiring layer, the first rewiring layer comprising a first side in contact with the separation layer and an opposing second side;
forming a conductive post electrically connected to the first rewiring layer on the second face of the first rewiring layer, and a first chip disposed on the second face of the first rewiring layer;
forming a laminate layer, and the laminate layer covering the conductive post and the first chip;
forming a second rewiring layer on the laminate layer, and the second rewiring layer being electrically connected to the conductive post and the first chip;
providing a substrate electrically connected to the second rewiring layer;
removing the temporary substrate and the separation layer to reveal a first side of the first rewiring layer;
forming a metal connecting post, and the metal connecting post perpendicularly penetrating the first rewiring layer in contact with the first chip;
bonding a second chip to a first side of the first rewiring layer, the second chip being electrically connected to the first rewiring layer, and the second chip being in contact with the metal connecting post;
bonding a heat sink element to the second chip.

Optionally, further comprising the step of forming a dummy wafer on a second side of the first rewiring layer, and the dummy wafer being symmetrically disposed on both sides of the first chip and fixedly connected to the first rewiring layer.

Optionally, there is further included the step of forming a dummy wafer on a first face of the first rewiring layer, and the dummy wafer is in contact with the metal connecting post.

Optionally, the step of forming the metallic connecting column comprises the step of forming a connecting through-hole using one of laser drilling, mechanical drilling, deep reactive ion etching, and light-assisted electrochemical etching, and the step of carrying out metal deposition to fill the connecting through-hole.

Optionally, prior to bonding the second chip on the first side of the first rewiring layer, a step of forming a recess in the first rewiring layer is included, wherein the method of forming the recess comprises a laser drilling process.

Optionally, the step of forming the plastisol layer comprises forming a plastisol layer on the first chip with an upper surface of the plastisol layer being higher than an upper surface of the first chip, performing a flattening process on the plastisol layer to reveal the first chip.

Optionally, the process for forming the laminate layer comprises one of a compression molding process, a transfer molding process, a liquid sealant curing molding process, a vacuum lamination process, and a spin-coating process; and the material of the laminate layer comprises one of an epoxy resin, a polyimide, and a silicone.

The present invention also provides a chip package structure, the chip package structure comprising: a substrate; a first rewiring layer, the first rewiring layer comprising opposing first and second sides; a second rewiring layer, the second rewiring layer comprising opposing first and second sides; a first chip, disposed between the second side of the first rewiring layer and the first side of the second rewiring layer and the first chip electrically connected to the second rewiring layer; a conductive post disposed between the second side of the first rewiring layer and the first side of the second rewiring layer and electrically connected to the first rewiring layer and the second rewiring layer; and a laminate layer disposed between the second side of the first rewiring layer and the first side of the second rewiring layer, encasing the first chip and the conductive post; a second chip disposed on the first side of the first rewiring layer; a metal connecting post, the metal connecting post perpendicularly penetrating the first rewiring layer and in contact with the first chip and the second chip; a heat sink element, the heat sink element in contact with the second chip.

Optionally, further comprising dummy wafers fixedly connected to the first rewiring layer and symmetrically disposed on both sides of the first chip, and/or disposed on a first side of the first rewiring layer, and the dummy wafers are in contact with the metal connecting posts.

Optionally, the heat dissipation element comprises a heat dissipation element with heat dissipation fins or a metal housing heat dissipation element.

As described above, the chip encapsulation structure and the preparation method of the present invention, by symmetrically introducing dummy wafers on both sides of the first chip, the thermal expansion coefficient of the dummy wafers can be reduced due to the lower thermal expansion coefficient of the dummy wafers, which can reduce the mismatch of thermal expansion coefficients of the encapsulation structure and reduce warping generated by the chip during the encapsulation process. By forming a metal connecting pillar between the first chip and the second chip on the outside of the laminate encapsulation layer, the heat dissipation channels are established, which further reduces the encapsulation thermal resistance and improves the heat dissipation efficiency of the chip, thereby forming a chip encapsulation structure with better heat dissipation performance.

### BRIEF DESCRIPTION OF THE DRAWINGS

FIG. 1 shows a flow chart of a method of preparing a chip package structure according to an embodiment of the present invention.

FIG. 2 shows a schematic cross-sectional diagram showing a structure after forming a temporary substrate and a separation layer according to an embodiment of the present invention.

FIG. 3 shows a schematic cross-sectional diagram showing a structure after forming the first rewiring layer according to embodiments of the present invention.

FIG. 4 shows a schematic cross-sectional diagram showing a structure after forming the conductive post and bonding the first chip according to embodiments of the present invention.

FIG. 5 shows a schematic cross-sectional diagram showing a structure after forming a laminate sealing layer according to an embodiment of the present invention provided.

FIG. 6 shows a schematic cross-sectional diagram showing a structure after performing a flattening process on a laminate layer according to an embodiment of the present invention.

FIG. 7 shows a schematic cross-sectional diagram showing a structure after forming the second rewiring layer according to embodiments of the present invention.

FIG. 8 shows a schematic cross-sectional diagram showing a structure after bonding a substrate according to an embodiment of the present invention.

FIG. 9 shows a schematic cross-sectional diagram showing a structure after removal of the temporary substrate and the separation layer according to embodiments of the present invention.

FIG. 10 shows a schematic cross-sectional diagram showing a structure of a metal connecting post after forming the metal connecting post according to an embodiment of the present invention.

FIG. 11 shows a schematic cross-sectional diagram showing a structure after bonding the second chip according to an embodiment of the present invention.

FIG. 12 shows a schematic cross-sectional diagram showing a structure after bonding the heat sink element according to embodiments of the present invention.

FIG. 13 shows a schematic structural diagram of a chip packaging structure according to embodiments of the present invention for forming a dummy wafer.

FIG. 14 shows a schematic structural diagram of another chip package structure according to an embodiment of the present invention.

### REFERENCE NUMERALS

101 temporary substrates
102 separation layer
103 first rewiring layer
1031 first side of 103
1032 second side of 103
104 first chip
105 conductive post
106 laminate layer
107 second rewiring layer
1071 first side of 107
1072 second side of 107
108 metal bump
109 metal connecting post
110 second chip
111 heat sink element
1111 heat sink fins
112 dummy wafer
113 substrates
S1-S10 steps

### DETAILED DESCRIPTION OF THE PREFERRED EMBODIMENTS

The specific embodiments are described below to illustrate the implementation of the present disclosure, and those skilled in the art can easily understand other advantages and effects of the present disclosure from the content disclosed in this specification. The present disclosure can also be implemented or applied in other specific embodiments. The details provided in this description can be modified or altered in various ways based on different perspectives and applications without departing from the spirit of the present disclosure.

For ease of description, spatial relationship terms such as “under,” “below,” “below,” “below,” “below,” “above,” “above,” “above,” and the like may be used herein to describe the relationship of an element or feature shown in the accompanying drawings to other elements or features, “above,” “on,” and the like to describe the relationship of one element or feature shown in the accompanying drawings to other elements or features. It will be appreciated that these spatial relationship terms are intended to encompass orientations of the device in use or operation other than those depicted in the accompanying drawings. Furthermore, when a layer is to be “between” two layers, it may be the only layer between the two layers, or there may be one or more intervening layers.

It is to be understood that the use of terms such as “first” and “second” to qualify the parts is only for the purpose of facilitating the differentiation of the parts, and the terms do not have special meanings if not otherwise declared, and therefore cannot be construed as a limitation of the scope of protection of the present invention. Therefore, they cannot be construed as a limitation of the scope of protection of the present invention.

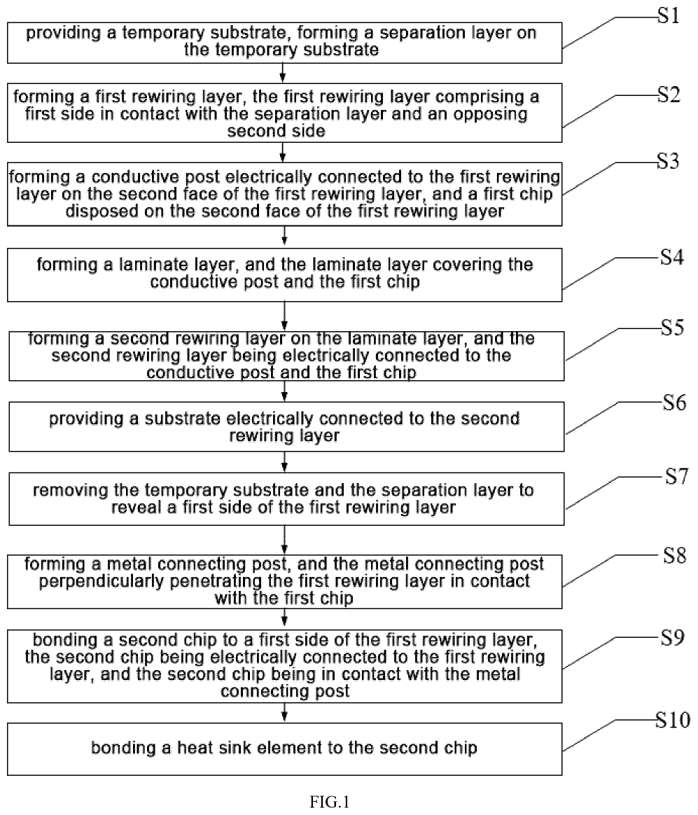

Referring to FIGS. 1 to 14, it should be noted that the illustrations provided in this embodiment only illustrate the basic concept of the present invention in a schematic manner, and the illustrations only show the components related to the present invention and are not drawn in accordance with the actual implementation of the number of components, shapes, and sizes of the actual implementation of the components of the type, number, and proportion may be an arbitrary change, and the layout of the components may be more complex.

### Embodiment 1

Referring to FIGS. 1 to 14, the present invention provides a method of preparing a chip encapsulation structure comprising the following steps:

S1: providing a temporary substrate 101, forming a separation layer 102 on the temporary substrate 101;

S2: forming a first rewiring layer 103, and the first rewiring layer 103 comprising a first face 1031 in contact with the separation layer 102 and an opposite second face 1032;

S3: forming a conductive post 105 electrically connected to the first rewiring layer 103 and a first chip 104 disposed on the second side 1032 of the first rewiring layer 103 on the second side 1032 of the first rewiring layer 103;

S4: forming a laminate layer 106, and the laminate layer 106 covering the conductive post 105 and the first chip 104;

S5: forming a second rewiring layer 107 on the laminate layer 106, and the second rewiring layer 107 being electrically connected to the conductive post 105 and the first chip 104;

S6: providing a substrate 113 electrically connected to the second rewiring layer 107;

S7: removing the temporary substrate 101 and the separation layer 102 to reveal a first side 1031 of the first rewiring layer 103;

S8: forming a metal connecting post 109, and the metal connecting post 109 perpendicularly penetrating the first rewiring layer 103 in contact with the first chip 104;

S9: bonding a second chip 110 to the first side 1031 of the first rewiring layer 103, the second chip 110 being electrically connected to the first rewiring layer 103 and the second chip 110 being in contact with the metal connecting post 109;

S10: bonding a heat sink element 111 on the second chip 110.

The method of preparing the chip package structure described in relation to the chip package structure is further described below in conjunction with the accompanying drawings, as follows:

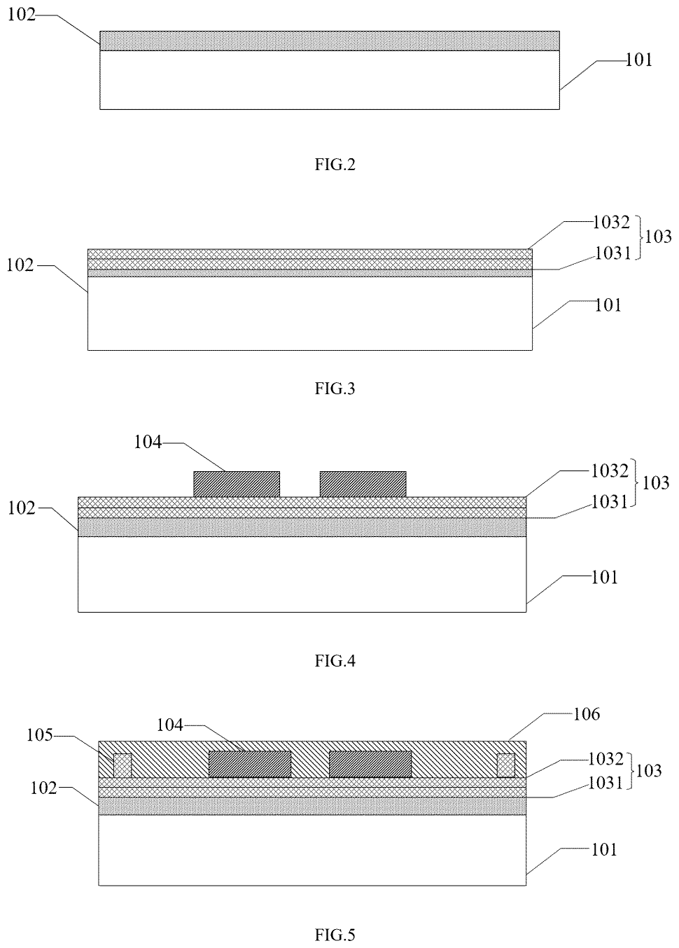

In step S1, referring to FIGS. 1 and 2, a temporary substrate 101 is provided and a separation layer 102 is formed on the temporary substrate 101.

Optionally, as shown in FIG. 2, the temporary substrate 101 includes one of silicon oxide substrate, glass substrate, ceramic substrate, polymer substrate, and other non-metallic materials, and its shape may be round, square, or any other desired shape, and its surface area is subject to being able to carry subsequent structures, which is not specifically limited herein, and is selected according to need.

Specifically, in this embodiment, a separation layer 102 is formed on the temporary substrate 101, the separation layer 102 comprising a layer of LTHC light-to-heat converting material having the property of being capable of adhering to other components and undergoing denaturing and peeling off after laser irradiation.

Specifically, in this embodiment, the temporary substrate 101 is selected to be a glass substrate with a lower coefficient of thermal expansion, on the one hand, the glass substrate has a lower coefficient of thermal expansion, which can reduce warping generated during the encapsulation process, on the other hand, the glass substrate has a lower cost, which makes it easy to form a separation layer on the surface thereof and reduces the difficulty of the subsequent removal process.

In step S2, referring to FIGS. 1 and 3, a first rewiring layer 103 is formed, the first rewiring layer 103 comprising a first face 1031 in contact with the separation layer 102 and an opposite second face 1032.

Optionally, the first rewiring layer 103 comprises at least one metallic wiring layer, with a metallic interconnect structure (not shown in the figure) formed in the first rewiring layer 103 to electrically connect the metallic wiring layers.

Optionally, the material of the metallic interconnect structure is one or a combination of copper, aluminum, nickel, gold, silver, and titanium. In this embodiment, the material of the metallic interconnect structure is preferably a copper block because copper blocks not only have good electrical conductivity, but also have characteristics such as very good ductility and ease of machining, thus helping to improve the performance of the semiconductor package structure. Of course, the material, the number of layers, and the distribution morphology of the metallic interconnection structure of the first rewiring layer 103 are set according to the actual needs and are not limited herein.

In step S3, referring to FIGS. 1 and 4, an electrically conductive post 105 electrically connected to the first rewiring layer 103, and a first chip 104 disposed on the second side 1032 of the first rewiring layer 103 are formed on the second side 1032 of the first rewiring layer 103.

Specifically, the conductive post 105 is disposed on the second side 1032 of the first rewiring layer 103 and is electrically connected to the first rewiring layer 103.

Optionally, the first chip 104 may be any existing semiconductor chip suitable for the package structure, and may be a plurality of chips of the same type or a plurality of different types, for example, it may be a system-on-chip (SOC) device or a memory chip such as an HBM, etc., which is set according to the actual needs, and is not specifically limited herein. In addition, based on the requirements of packaging efficiency, packaging size, etc., a plurality of the first chips 104 are generally molded at the same time, and in this embodiment the number of the first chips 104 is shown to be 2. However, the number of the first chips 104 is not limited thereto, and the number of the first chips 104 may be greater than or equal to 2 based on the requirements, such as 3, 4, 5, or more.

Optionally, as shown in FIG. 13, in other embodiments, further comprising the step of forming a dummy wafer 112 on the second side 1032 of the first rewiring layer 103, and the dummy wafer 112 being symmetrically disposed on both sides of the first chip 104 and fixedly coupled to the first rewiring 103 layer to reduce the deformation of the package structure by the dummy wafer 112, wherein the dummy wafer 112 is a passive chip that may not perform any electrical function and is electrically isolated from other components in the package structure (e.g., first rewiring layer 103), and the dummy wafer 112 is mechanically coupled to the first rewiring layer 103 in a manner that is not limited to adhesive connection. In this embodiment the number of the dummy wafers 112 is shown as 2, but the number of the dummy wafers 112 is not limited to this, depending on the demand the number of the dummy wafers 112 may be greater than or equal to 2, such as 3, 4 or more.

Optionally, the dummy wafer 112 may be a pure silicon block to increase the amount of semiconductor material in this package and to reduce the coefficient of thermal expansion mismatch of the package structure. Of course, in other embodiments, the dummy wafers 112 may be other suitable materials for reducing the effective coefficient of thermal expansion of the package structure.

In step S4, referring to FIG. 1, FIG. 5 and FIG. 6, a plastisol layer 106 is formed, the plastisol layer 106 covering the electrically conductive post 105 and the first chip 104.

Specifically, as shown in FIGS. 5 and 6, the step of forming the plastisol layer 106 comprises: forming a plastisol layer 106 on the first chip 104 with an upper surface of the plastisol layer 106 being higher than an upper surface of the first chip 104, performing a flattening process on the plastisol layer 106 to reveal the first chip 104.

Specifically, a flattening process is executed after the formation of the laminate layer 106 to maintain a suitable thickness of the encapsulated structure, which is conducive to reducing the size of the encapsulated structure and improving the quality of the encapsulation.

Optionally, the flattening process comprises one of a grinding process, a chemical-mechanical grinding process, a dry grinding process, an etching process, a dicing process, or a combination thereof. After the flattening process, the surface of the laminate layer 106 is substantially flush with the surface of the first chip 104.

Optionally, the process for forming the laminate layer 106 comprises one of a compression molding process, a transfer molding process, a liquid sealant curing and molding process, a vacuum lamination process, and a spin-coating process; and the material of the laminate layer 106 comprises one of an epoxy resin, a polyimide, and a silicone.

Specifically, the plastic sealing material becomes liquid after heating, and the pressing is implemented in a high temperature environment, under which pressure the first chip 104 will produce warpage, so introducing the dummy wafer 112 in the first chip 104 can reduce the thermal expansion coefficient mismatch of the encapsulation structure due to the lower thermal expansion coefficient of the dummy wafer 112, and thus can reduce the warpage produced by the first chip 104 in the encapsulation process warpage of the first chip 104 during the packaging process.

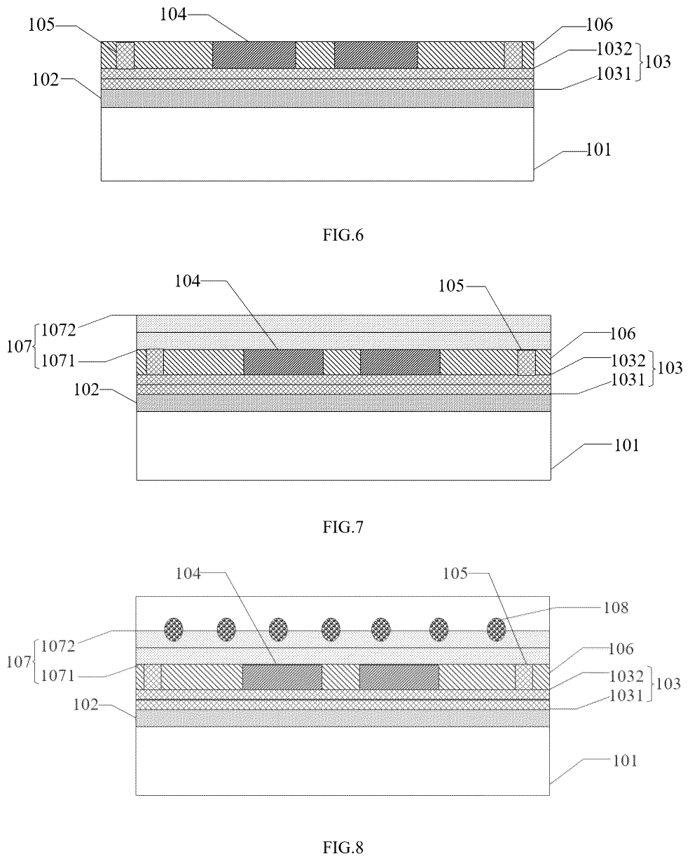

In step S5, referring to FIGS. 1 and 7, a second rewiring layer 107 is formed on the laminate layer 106, the second rewiring layer 107 being electrically connected to the conductive post 105 and the first chip 104.

Specifically, as shown in FIG. 7, the second rewiring layer 107 comprises a first side 1071 electrically connected to the first chip 104 and an opposing second side 1072, and the process and materials used to form the second rewiring layer 107 are consistent with those of the first rewiring layer 103, and will not be repeated herein.

In step S6, referring to FIGS. 1 and 8, a substrate 113 electrically connected to the second rewiring layer 107 is provided.

Optionally, the substrate 113 comprises a wafer-level substrate, the substrate 113 may be one of a silicon oxide substrate, a glass substrate, a ceramic substrate, an organic substrate, and may have a shape of a circle, a square, or any other desired shape.

Specifically, as shown in FIG. 8, in this embodiment, a laser drilling process is used to form the recess in the substrate 113, and a reflow process is used to form a metal bump 108 in the recess to realize an electrical connection between the second rewiring layer 107 and the substrate 113.

Optionally, the metal bump 108 comprises one of a gold-tin solder ball, a silver-tin solder ball, and a copper-tin solder ball. Of course, the metal bumps 108 may also be formed by a ball-planting process, which is not limited herein.

In step S7, referring to FIGS. 1 and 9, the temporary substrate 101 and the separation layer 102 are removed, revealing a first side 1031 of the first rewiring layer 103.

Optionally, the separation layer 102 and the temporary substrate 101 are removed and the package structure is flip-flopped to reveal the first side 1031 of the first rewiring layer 103.

Specifically, as shown in FIG. 9, the separation layer 102 and the temporary substrate 101 are removed by removing the conductive post 105, the first chip 104, and the first rewiring layer 103, which are molded, from the temporary substrate 101 and inverted to

### Reveal a First Side 1031 of the First Rewiring Layer 103.

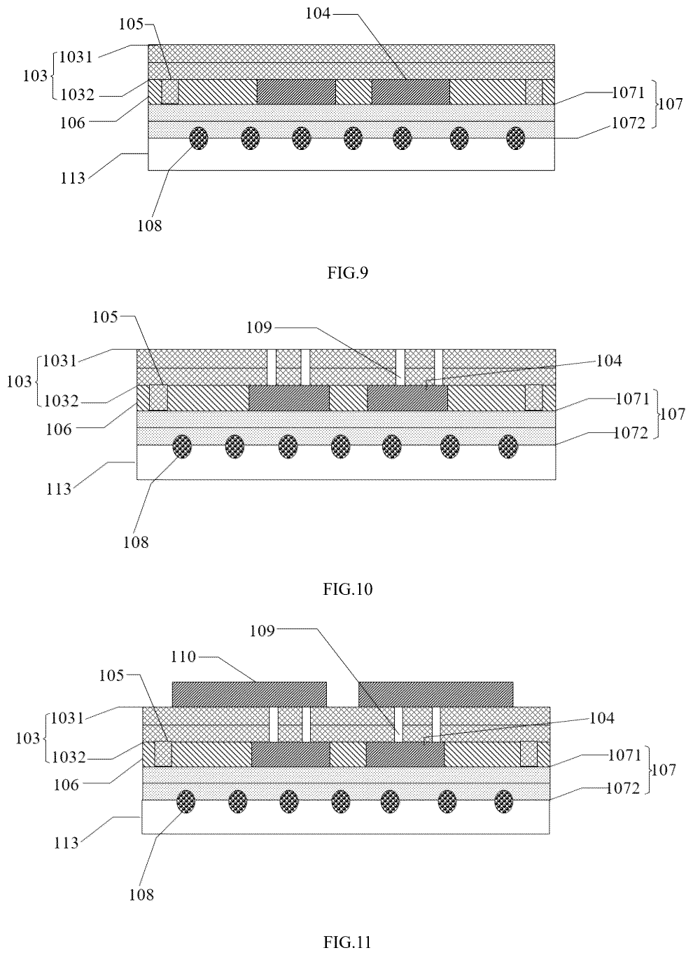

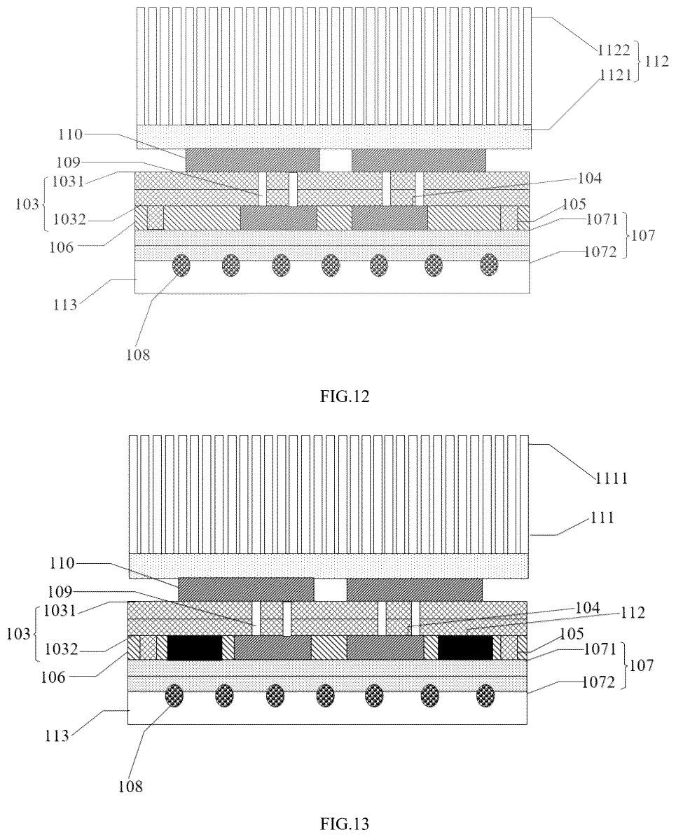

In step S8, referring to FIGS. 1 and 10, a metal connecting post 109 is formed, the metal connecting post 109 perpendicularly penetrating the first rewiring layer 103 in contact with the first chip 104.

Optionally, the step of forming the metal connecting post 109 comprises the step of forming a connecting through-hole using one of laser drilling, mechanical drilling, deep reactive ion etching, and light-assisted electrochemical etching, and the step of carrying out metal deposition to fill the connecting through-hole.

Specifically, in this embodiment, the process of laser drilling and metal deposition is selected to form the metal connecting post 109, the metal connecting post 109 perpendicularly penetrating the first rewiring layer 103 and in contact with the first chip 104. The laser drilling process is highly accurate and controllable, and is capable of accurately forming the metal connecting post 109 without affecting other structures.

Optionally, the metal connecting post 109 is made of one of copper, aluminum, gold, silver, nickel, titanium, and the like.

In step S9, referring to FIGS. 1 and 11, a second chip 110 is bonded to the first side 1031 of the first rewiring layer 103, the second chip 110 is electrically connected to the first rewiring layer 103, and the second chip 110 is in contact with the metal connecting post 109.

Specifically, as shown in FIG. 11, the second chip 110 is connected to the first chip 104 through the metal connecting post 109, such that heat generated by the first chip 104 during the packaging process can be quickly transferred to the second chip 110 through the metal connecting post 109.

Optionally, as shown in FIG. 14, in other embodiments, there is also included the step of forming a dummy wafer 112 on the first side 1031 of the first rewiring layer 103, and the dummy wafer 112 is in contact with the metal connecting post 109 to fill the package structure by the dummy wafer 112, and which can improve the thermal efficiency of the chip. Wherein the dummy wafer 112 is a passive chip that may not perform any electrical function and is electrically isolated from other components in the package structure. In this embodiment the number of the dummy wafers 112 is shown as 1, but the number of the dummy wafers 112 is not limited to this, depending on the demand the number of the dummy wafers 112 may be greater than or equal to 1, such as 2, 3 or more.

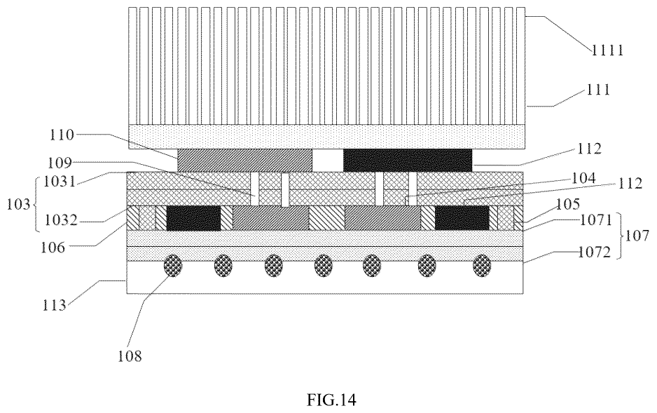

In step S10, referring to FIGS. 1 and 12, a heat sink element 111 is bonded on the second chip 110.

Optionally, the heat sink element 111 comprises a heat sink element 111 with heat sink fins 1111, or a metal-cased heat sink element.

Specifically, as shown in FIG. 12, in this embodiment, the heat sink element 111 is a heat sink element with heat sink fins 1111. The heat dissipation element 111 is electrically connected to the second chip 110, so that the heat generated by the first chip 104 in the encapsulation process is quickly transferred to the second chip 110 through the metal connecting post 109, which in turn is quickly dissipated through the heat dissipation element 111, thereby further improving the heat dissipation efficiency of the encapsulation structure.

### Embodiment 2

As shown in FIG. 14, this embodiment provides a chip packaging structure comprising:
Baseboard 113;
A first rewiring layer 103, the first rewiring layer 103 comprising an opposing first side 1031 and a second side 1032;
A second rewiring layer 107, the second rewiring layer 107 comprising an opposing first side 1071 and a second side 1072;
A first chip 104, disposed between a second side 1032 of the first rewiring layer 103 and a first side 1071 of the second rewiring layer 107, and the first chip 104 is electrically connected to the second rewiring layer 107;
A conductive post 105, disposed between a second side 1032 of the first rewiring layer 103 and a first side 1071 of the second rewiring layer 107, and electrically connected to the first rewiring layer 103 and the second rewiring layer 107;
A laminate layer 106, disposed between a second side 1032 of the first rewiring layer 103 and a first side 1071 of the second rewiring layer 107, encasing the first chip 104 and the conductive post 105;
A second chip 110, disposed on a first side 1031 of the first rewiring layer 103;
A metal connecting post 109, the metal connecting post 109 perpendicularly penetrating the first rewiring layer 103 and in contact with the first chip 104 and the second chip 110;
A heat sink element 111, the heat sink element 111 being in contact with the second chip 110.

With respect to the preparation of the chip package structure, reference may be made to the above preparation method, but is not limited thereto, in this embodiment, the chip package structure is prepared using the above preparation method, so that with respect to the preparation of the chip package structure, the selection of materials and the like, reference may be made to Embodiment I, which will not be repeated herein.

Optionally, as shown in FIGS. 13 and 14, further comprising dummy wafers 112 fixedly connected to the first rewiring layer 103 and symmetrically disposed on both sides of the first chip 104, and/or disposed on the first side 1031 of the first rewiring layer 103, and the dummy wafers 112 are in contact with the metal connecting posts 109.

Optionally, as shown in FIG. 14, the heat sink element 111 comprises a heat sink element with heat sink fins 1111, or a metal housing heat sink element.

In summary, the present invention provides a chip encapsulation structure and a method of preparing the same. The chip encapsulation structure comprises: a substrate;

a first rewiring layer, the first rewiring layer comprising opposing first and second sides; a second rewiring layer, the second rewiring layer comprising opposing first and second sides; a first chip disposed between the second side of the first rewiring layer and the first side of the second rewiring layer and the first chip is electrically coupled with the second rewiring layer; a dummy wafer, the dummy wafer is fixedly coupled and symmetrically disposed with the first rewiring layer, the dummy wafer being fixedly connected to the first rewiring layer and symmetrically distributed on both sides of the first chip, a conductive post located between the second side of the first rewiring layer and the first side of the second rewiring layer and being electrically connected to the first rewiring layer and the second rewiring layer, a laminate layer located between the second side of the first rewiring layer and the first side of the second rewiring layer, covering the first chip and the conductive post; a second layer, located between the first chip and the second rewiring layer and being electrically connected to the first chip and the conductive post; and first chip and the electrically conductive post; a second chip disposed on the first side of the first rewiring layer; a metal connecting post, the metal connecting post perpendicularly perpendicular to the first rewiring layer and in contact with the first chip and the second chip; and a heat sink element, the heat sink element in contact with the second chip. By symmetrically introducing dummy wafers on both sides of the first chip, the present invention can reduce the thermal expansion coefficient mismatch of the encapsulation structure due to the lower thermal expansion coefficient of the dummy wafers, thereby reducing the warping generated by the chip during the encapsulation process; by forming a metal connecting column between the first chip and the second chip on the outside of the laminate encapsulation layer, a heat dissipation channel can be established, which further reduces the encapsulation thermal resistance and improves the chip's heat dissipation efficiency, thereby forming a chip encapsulation structure with better heat dissipation performance. The present disclosure effectively addresses the limitations of existing technologies, making it highly valuable for industrial applications.

The embodiments described above serve merely as illustrative examples of the principles and effects of the present invention, and are not intended to serve as limitations on the present invention. Persons skilled in the art may modify or alter these embodiments without departing from the spirit and scope of the present disclosure. Accordingly, all equivalent modifications or alterations accomplished by persons having ordinary knowledge of the art without departing from the spirit and technical ideas disclosed herein shall still be covered by the claims of the present invention.

1. A method of preparing a chip encapsulation structure, comprising steps of:
providing a temporary substrate and forming a separation layer on the temporary substrate;
forming a first rewiring layer, wherein the first rewiring layer has a first side in contact with the separation layer and an opposing second side;
forming a conductive post electrically connected to the second side of the first rewiring layer, and disposing a first chip on the second side of the first rewiring layer;
forming a laminate layer, wherein the laminate layer covers the conductive post and the first chip;
forming a second rewiring layer on the laminate layer, wherein the second rewiring layer is electrically connected to the conductive post and the first chip;
providing a substrate electrically connected to the second rewiring layer;
removing the temporary substrate and the separation layer to expose the first side of the first rewiring layer;
forming a metal connecting post, wherein the metal connecting post perpendicularly penetrates the first rewiring layer in contact with the first chip;
bonding a second chip to a first side of the first rewiring layer, wherein the second chip is electrically connected to the first rewiring layer and the metal connecting post; and
bonding a heat sink element to the second chip.

2. The method of preparing the chip encapsulation structure according to claim 1, further comprising a step of forming dummy wafers on the second side of the first rewiring layer, and wherein the dummy wafers are symmetrically disposed on both sides of the first chip and connected to the first rewiring layer at fixed positions, wherein a thermal expansion coefficient of the dummy wafer is lower than a thermal expansion coefficient of the first chip and the second chip.

3. The method of preparing the chip encapsulation according to claim 1, characterized in that it further comprises the step of forming a dummy wafer on a first side of the first rewiring layer, and the dummy wafer is in contact with the metal connecting post.

4. The method of preparing the chip encapsulation according to claim 1, wherein the step of forming the metal connecting post further comprises a step of forming a connecting through-hole by employing one of laser drilling, mechanical drilling, deep reactive ion etching, and light-assisted electrochemical etching, followed by a step of carrying out metal deposition to fill the connecting through-hole.

5. The method of preparing the chip encapsulation according to claim 1, prior to bonding the second chip on the first side of the first rewiring layer, further comprising a step of forming a recess in the first rewiring layer, wherein the step of forming the recess comprises a laser drilling process.

6. The method of preparing the chip encapsulation according to claim 1, wherein the laminate layer is formed on the first chip, wherein an upper surface of the laminate layer is higher than an upper surface of the first chip, and wherein a flattening process is performed on the laminate layer to expose the first chip.

7. The method of preparing the chip encapsulation according to claim 1, wherein the step of forming the laminate layer includes one of a compression molding process, a transfer molding process, a liquid sealant curing and molding process, a vacuum laminating process, and a spin-coating process; and wherein a material of the laminate layer includes one of an epoxy resin, a polyimide, and a silica gel.

8. A chip package structure comprising:
a substrate;
a first rewiring layer, having a first side and a second side opposing the first side;
a second rewiring layer, wherein the second rewiring layer comprises a first side and an opposing second side;
a first chip disposed between a second side of the first rewiring layer and a first side of the second rewiring layer, and wherein the first chip is electrically connected to the second rewiring layer;
an electrically conductive post disposed between a second side of the first rewiring layer and a first side of the second rewiring layer and electrically connected to the first rewiring layer and the second rewiring layer;
a laminate layer disposed between the second side of the first rewiring layer and the first side of the second rewiring layer, wherein the laminate layer encases the first chip and the conductive post;
a second chip disposed on the first side of the first rewiring layer;
a metal connecting post perpendicularly penetrating the first rewiring layer, wherein the metal connecting post is in contact with the first chip and the second chip; and
a heat sink element in contact with the second chip.

9. The chip package structure according to claim 8, further comprises dummy wafers connected to the first rewiring layer at fixed locations and symmetrically disposed on both sides of the first chip, and/or disposed on a first side of the first rewiring layer, and the dummy wafers are in contact with the metal connecting post, wherein the dummy wafers have a lower thermal expansion coefficient than that of the first chip.

10. The chip package structure according to claim 8, wherein the heat sink element comprises a heat dissipation base with heat dissipation fins, or a metal shell heat dissipation element.
